(19) United States
(12) Patent Application Publication
(10) Pub. No.: US 2003/0089957 A1
(43) Pub. Date: May 15, 2003

(54) Heat regulating device for integrated optical devices

(75) Inventor: Marianne Anton, Oxford (GB)

Correspondence Address: FLESHNER & KIM, LLP, P.O. BOX 221200, CHANTILLY, VA, 20153, US

(73) Assignee: Bookham Technology plc

(21) Appl. No.: 10/268,672

(22) Filed: Oct. 11, 2002

(30) Foreign Application Priority Data
Nov. 14, 2001 (GB) 0127305.1

(51) Int. Cl. H01L 31/0203

(52) U.S. Cl. 257/433

(57) ABSTRACT

An integrated optical package comprises an integrated optical device supported on a carrier with a gelatinous material therebetween to assist in heat conduction. The carrier can include a thermal regulating device such as a heat sink or heater for regulating the temperature of the integrated optical device via the gelatinous material. The gelatinous material can include a metallic second phase suspended in the gelatinous material, to improve its thermal conductivity. The maximum dimension of the particles is ideally smaller than the gap between the integrated optical device and the carrier in which the gelatinous material is located, such as in the 5 to 95 percent range of the dimension of the gap. The particles of the metallic second phase can be elongate, in which case they can be aligned with each other such as in a direction extending from the integrated optical device towards the carrier. Alternatively, they can be substantially spherical. Ferromagnetic particles are easier to align by using a magnetic field. A method is also disclosed, comprising the steps of disposing a closed loop of adhesive, thus forming a well, on one or the other of the integrated optical device or the carrier, placing a gelatinous material into said well, placing the other of the carrier or integrated optical device in contact with the adhesive layer and gelatinous material, and curing the adhesive to secure the integrated optical device to the carrier. The gelatinous material can be thixotropic.

### FIELD OF THE INVENTION

The present invention relates to the regulation of temperature in an optical integrated device. It particularly, but not exclusively, addresses the problem of maintaining a uniform temperature over the plane of the optical integrated device with substantially no temperature variations thereon.

### BACKGROUND ART

Many integrated optical devices demand a high degree of stability in their operating temperature, due to the free space interconnections of optical data, e.g. in an arrayed waveguide. Variations or “hot spots” in temperature over the plane of the integrated optical device, even by a small fraction of a degree can result in poor performance and unacceptable optical losses. This is due to the fact that the refractive index of integrated optical components changes with temperature and this affects the paths of the light as it traverses the chip.

### SUMMARY OF THE INVENTION

The present invention provides an improved method and integrated optical package which maintains the temperature of the chip in a stable manner.

According to a first aspect of the invention there is provided an integrated optical package, comprising an integrated optical device supported on a carrier, with a gelatinous material therebetween.

The integrated optical package can include a thermal regulating device mounted on the carrier, for regulating the temperature of the integrated optical device via the gelatinous material.

Further preferred and optional features of the invention will be apparent from the following description and from the subsidiary claims of the patent specification.

### BRIEF DESCRIPTION OF THE DRAWINGS

The invention will now be further described, by way of example, with reference to the accompanying figures, in which:

FIG. 1 is a perspective view of the integrated optical package according to a first embodiment of the present invention;

FIG. 2 is an end-on view of the integrated optical package of FIG. 1;

FIG. 3 is a top view of the integrated optical package of FIG. 1; and

FIG. 4 is an end-on view of the integrated optical package according to a second embodiment of the present invention.

### DETAILED DESCRIPTION OF THE EMBODIMENT

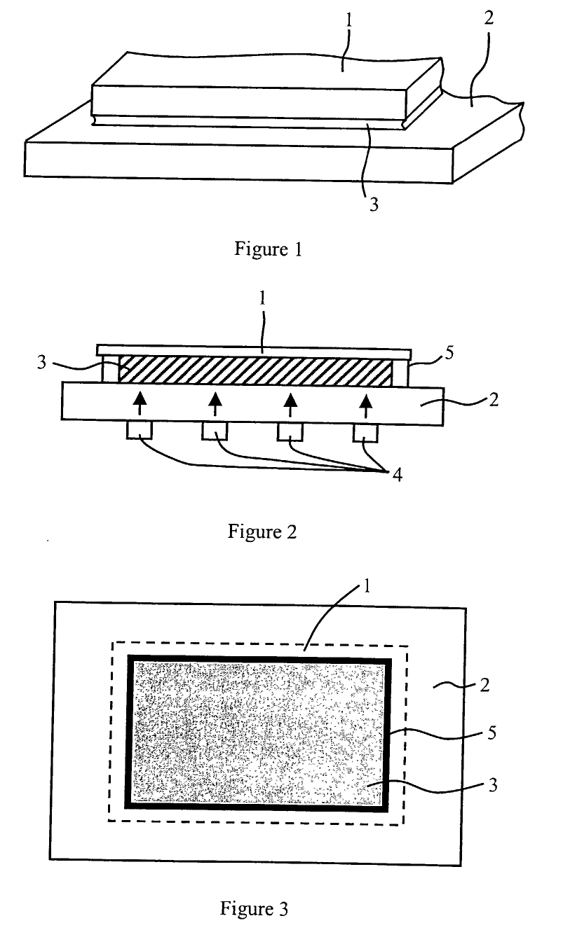

FIG. 1 shows an integrated optical device 1, preferably a silicon-on-insulator device, supported on a ceramic substrate 2 with a layer of gelatinous material 3 therebetween. The gelatinous material is preferably a thixotropic material, so that its viscosity increases as the shear rate decreases, that is that the material thickens and firms to a gelatinous form as its handling decreases.

FIG. 2 shows an array of heating elements 4, e.g. a layer of deposited resistive material, disposed on the underside of the supporting, ceramic substrate 2 so as to provide heat to the integrated optical device supported thereon. FIG. 2 also shows side walls 5 of an adhesive material, e.g. a UV curable adhesive. These are used to adhere the integrated optical device 1 to the ceramic support 2. The UV curable adhesive side walls 5 also serve to provide a containment surround for the gelatinous material 2 contained therein.

If it is desired to dissipate heat away from the integrated optical device, the array of hearing elements, can be replaced by an array of thermo-electric devices, which act to cool the integrated optical device. It is irrelevant whether the device is heated or cooled; the invention seeks to provide a better transfer of heat, regardless of direction.

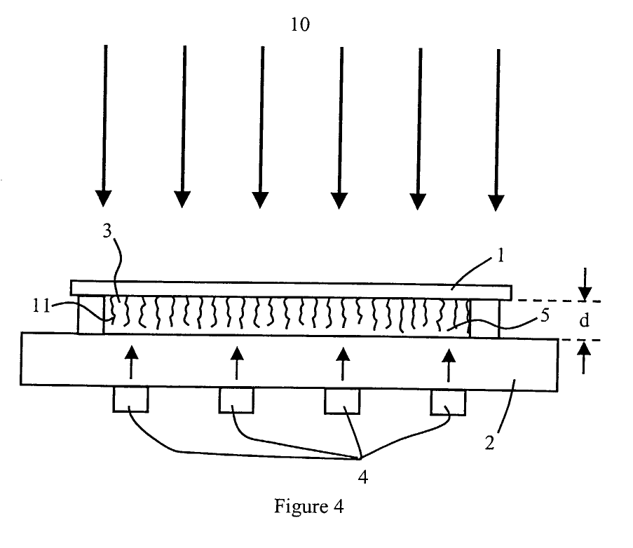

FIG. 3 shows the integrated optical device 1 (in dotted lines for clarity) in place supported on the ceramic substrate 2. The UV curable adhesive 5 is placed on the ceramic substrate 2 such that it forms a closed well around an area where the gelatinous material 3 is to be placed. The thixotropic gelatinous material 3 is then placed within the well created by the adhesive 5 and is thus contained therein. The integrated optical device 1 is then placed on the supporting ceramic substrate 2 and is held in place by curing the adhesive 5. The gelatinous material 3 is thus contained in a layer both in contact with the ceramic substrate 2 and the integrated optical device 1. The now viscous gelatinous material 3 serves to convey heat from the heating elements 4 by conduction to the integrated optical device such that there are no local “hot spots” or temperature variations in the integrated optical device thereon. The gelatinous material 3 thus acts as a heat spreader.

It will be appreciated that the adhesive 5 may be placed on the integrated optical device 1 rather than the ceramic substrate 2, the gelatinous material placed within the closed loop of adhesive 5 and the ceramic substrate then placed on the integrated optical device.

FIG. 4 shows an alternative method whereby the integrated optical package can be made. The adhesive layer 5, e.g. a UV curable adhesive, is again placed so as to form a closed well around the perimeter of the placement of the integrated optical device 1. The well thus formed is filled with a gelatinous material containing a metallic second phase 11. The metallic second phase may be composed of a number of suitable metals, including silver, copper, iron, nickel or cobalt. The gelatinous material is again preferably thixotropic. Several such gelatinous materials are available, such as Sylgel 1612 (Wacker Chemical) and RBC-6100 (RBC Epoxy).

The metallic second phase may comprise metal filings or chips of a suitable size such that their maximum dimension is smaller than the gap, of dimension d, between the ceramic substrate and the integrated optical device 1 placed thereon. The gap d may be in the range 5 to 500 microns, but is typically in the range 50 to 200 microns. In general, smaller particles are less likely to move less within the gel.

The metallic particles are preferably ferromagnetic such as to be aligned by applying a magnetic field 10 within the vicinity of the integrated optical package such that the metallic particles 11 are brought into contact with the undermost surface of the integrated optical device 1 and are thus suspended within the gelatinous material 3. Suitable ferromagnetic materials are iron, nickel, cobalt, Au₂MnAl, Cu₂MnAl, Cu₂MnIn and the like. Other non-ferromagnetic materials such as silver and copper can, however, be used. The particles can be coated to improve their corrosion properties, such as with silver, tin or gold.

The metallic particles 11 have the effect of increasing the effective surface area of the undermost side of the integrated optical device 1, so increasing the thermal contact between the integrated optical device 1 and the gelatinous material 3, thus assisting in maintaining a uniform temperature over the surface of the integrated optical device.

Other methods of aligning the metallic particles 11 may also be used, such as the application of an electric field. The metallic particles 11 may also be formed in shapes other than elongate. For example, small spheres may be used, the diameters of which are less than the gap d between the ceramic substrate 2 and the integrated optical device 1. In practice, the difference in dimension between the metallic particles 11 and the gap d should be such that no undue stresses are placed on the integrated optical device 1.

1. An integrated optical package comprising an integrated optical device supported on a carrier with a gelatinous material therebetween.

2. An integrated optical package according to claim 1 in which the carrier includes a thermal regulating device for regulating the temperature of the integrated optical device via the gelatinous material.

3. An integrated optical package according to claim 2 in which the thermal regulating device is a heat sink.

4. An integrated optical package according to a claim 2 in which the thermal regulating device is a heater.

5. An integrated optical package according to claim 1 in which the integrated optical device is a silicon-based device.

6. An integrated optical package according to claim 1 in which the integrated optical device is a silicon-on-insulator, SOI device.

7. An integrated optical package according to claim 1 in which the integrated optical device comprises a plurality of waveguides for optical modes.

8. An integrated optical device according to claim 1 in which the waveguides are rib waveguides.

9. An integrated optical package according to claim 1 in which the gelatinous material includes a metallic second phase.

10. An integrated optical package according to claim 9 in which the metallic second phase is suspended in the gelatinous material.

11. An integrated optical package according to claim 9 in which the metallic second phase consists of particles of a maximum dimension which is smaller than a gap between the integrated optical device and the carrier in which the gelatinous material is located.

12. An integrated optical package according to claim 11 in which the metallic second phase consists of particles of a maximum dimension which is in the 5 to 95 percent range of the dimension of the gap.

13. An integrated optical package according to claim 9 in which the particles of the metallic second phase comprises elongate particles.

14. An integrated optical package according to claim 13 in which the elongate particles are aligned with each other.

15. An integrated optical package according to claim 14 in which the elongate particles are aligned in a direction extending from the integrated optical device towards the carrier.

16. An integrated optical package according to claim 9 in which the metallic second phase comprises substantially spherical particles.

17. An integrated optical package according to claim 11 in which the particles are ferromagnetic.

18. An integrated optical package according to claim 1 including an adhesive layer disposed around the perimeter of the gelatinous material to affix the integrated optical device to the carrier.

19. A method of fabricating an integrated optical package, comprising the steps of:
disposing a closed loop of adhesive, thus forming a well, on one or the other of the integrated optical device or the carrier;
placing a gelatinous material into said well;
placing the other of the carrier or integrated optical device in contact with the adhesive layer and gelatinous material;
curing the adhesive to secure the integrated optical device to the carrier.

20. A method of fabricating an integrated optical package, according to claim 20 in which the gelatinous material is a thixotropic gelatinous material.

21. A method of fabricating an integrated optical package, according to claim 19 in which the gelatinous material comprises a metallic second phase.

22. A method of fabricating an integrated optical package, according to claim 21, in which a magnetic or electric field is applied to align the metallic second phase where the metallic second phase comprises elongate particles.

23. A method of fabricating an integrated optical package, according to claim 21 in which the elongate particles are aligned in a direction extending from the integrated optical device towards the carrier.
